(19) United States
(12) Patent Application Publication
(10) Pub. No.: US 2025/0227836 A1
(43) Pub. Date: Jul. 10, 2025

(54) ELECTRONIC DEVICE AND IMPEDANCE MEASUREMENT METHOD

(71) Applicant: InnoLux Corporation, Miao-Li County (TW)

(72) Inventors: Cheng-Yeh TSAO, Miao-Li County (TW); Chia-Hao WU, Miao-Li County (TW); Chi-Hung CHANG, Miao-Li County (TW)

(21) Appl. No.: 18/973,509

(22) Filed: Dec. 9, 2024

(30) Foreign Application Priority Data
Jan. 4, 2024 (CN) 202410014193.X

(51) Int. Cl. H05K 1/02; G01R 27/02; H05K 7/14

(52) U.S. Cl. CPC H05K 1/0213; G01R 27/02; H05K 1/0277; H05K 7/1427; H05K 2201/055

(57) ABSTRACT

An electronic device is provided. The electronic device includes a housing, a panel, and a circuit board. The panel is disposed on the housing. The circuit board is electrically connected to the panel. The circuit board has a first ground terminal and a second ground terminal. The first ground terminal and the second ground terminal have no electrical connection path within the circuit board. The first ground terminal is electrically connected to the housing through a first conductive medium, and the second ground terminal is electrically connected to the housing through a second conductive medium.

### CROSS REFERENCE TO RELATED APPLICATIONS

This application claims priority of China Patent Application No. 202410014193.X filed on Jan. 4, 2024, the entirety of which is incorporated by reference herein.

### BACKGROUND

### Technical Field

The present disclosure relates to electronic devices, and in particular it relates to an electronic device with multiple ground terminals.

### Description of the Related Art

As the application of electronic devices continues to advance, the development of display technology is also changing with each passing day. However, in the face of different manufacturing technical conditions, the requirements on the structure and quality of electronic devices are getting higher and higher, causing the manufacturers of electronic devices to face different challenges.

In display products that include circuit boards, if the impedance of the conductive housing in contact with the circuit board and serving as a ground is too high, ghost points may occur in the display area of the panel. Therefore, it is necessary to measure the impedance of the conductive housing.

In the impedance measurements of previous conductive housings, it was necessary to use an additional test platform to measure the impedance of the previous conductive housings. For example, a test platform configured with conductive foam and a test board may be used to test the impedance of a conductive housing. However, these additional facilities will increase manufacturing costs, and the conductive foam may have the problem of incomplete electrical contact.

In summary, although existing electronic devices can generally meet their original intended uses, they still do not fully meet the needs in all respects. For example, how to reduce the cost of electrical testing while achieving their original functions by improving the design of electronic devices is still a topic that the industry is currently studying. Therefore, the research and development of electronic devices requires continuous updates and adjustments to solve various problems faced by the manufacturers of electronic devices.

### BRIEF SUMMARY

The present disclosure provides an electronic device. The electronic device includes a housing, a panel, and a circuit board. The panel is disposed on the housing. The circuit board is electrically connected to the panel. The circuit board has a first ground terminal and a second ground terminal. The first ground terminal and the second ground terminal have no electrical connection path within the circuit board. The first ground terminal is electrically connected to the housing through a first conductive medium, and the second ground terminal is electrically connected to the housing through a second conductive medium.

The present disclosure also provides an impedance measurement method. The method includes disposing a housing. The method also includes disposing a circuit board. The circuit board has a first ground terminal and a second ground terminal. The first ground terminal and the second ground terminal have no electrical connection path within the circuit board. The first ground terminal is electrically connected to the housing through a first conductive medium, and the second ground terminal is electrically connected to the housing through a second conductive medium. The method also includes disposing a test board to provide a constant current to the first ground terminal and output a voltage value. The method also includes measuring an impedance value through the voltage value.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion

FIG. 1 illustrates a schematic diagram of an electrical measurement method of an electronic device, in accordance with some embodiments of the present disclosure.

FIG. 2A illustrates a cross-sectional view of the electronic device, in accordance with some embodiments of the present disclosure.

FIG. 2B illustrates a local cross-sectional view of the electronic device as shown in FIG. 2A, in accordance with some embodiments of the present disclosure.

FIG. 3A illustrates a schematic top view depicting a routing design of a circuit board, in accordance with some embodiments of the present disclosure.

FIG. 3B illustrates a side view of the electronic device corresponding to a section line A-A in FIG. 3A and viewed along the Y direction, in accordance with some embodiments of the present disclosure.

FIG. 3C illustrates a side view of another electronic device corresponding to the section line A-A in FIG. 3A and viewed along the Y direction, in accordance with some other embodiments of the present disclosure.

FIG. 4A illustrates a schematic top view depicting a routing design of the circuit board, in accordance with some embodiments of the present disclosure.

FIG. 4B illustrates a local cross-sectional view of the circuit board including a first ground terminal having a smaller first characteristic length, in accordance with some embodiments of the present disclosure.

FIG. 4C illustrates a local cross-sectional view of the circuit board including a first ground terminal having a larger first characteristic length, in accordance with some embodiments of the present disclosure.

FIG. 5 illustrates a schematic top view depicting a routing design of the circuit board, in accordance with some embodiments of the present disclosure.

FIG. 6A illustrates a schematic top view depicting a routing design of the circuit board, in accordance with some embodiments of the present disclosure.

FIG. 6B illustrates a side view of the electronic device corresponding to a section line B-B in FIG. 6A and viewed along the Y direction, in accordance with some embodiments of the present disclosure.

FIG. 7 illustrates a schematic top view depicting a routing design of the circuit board, in accordance with some embodiments of the present disclosure.

FIG. 8 illustrates a schematic top view depicting a routing design of the circuit board, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “about”, “approximately”, and “substantially” used herein generally refer to a given value or a range within 20 percent, preferably within 10 percent, and more preferably within 5 percent, within 3 percent, within 2 percent, within 1 percent, or within 0.5 percent. It should be noted that the amounts provided in the specification are approximate amounts, which means that even “about”, “approximate”, or “substantially” are not specified, the meanings of “about”, “approximate”, or “substantially” are still implied.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

The term “substantially” as used herein indicates the value of a given quantity that can vary based on a particular technology node associated with the subject semiconductor device. In some embodiments, based on the particular technology node, the term “substantially” can indicate a value of a given quantity that varies within, for example, ±5% of a target (or intended) value.

In the present disclosure, the length, thickness, width, height, distance and area can be measured using an optical microscope (OM), an electron microscope (such as a scanning electron microscope (SEM)) or measured by other methods, but not limited to this.

It should be understood that the electronic device of the present disclosure may include a display device, a backlight device, an antenna device, a sensing device or a splicing device, but not limited to this. The electronic device may be a bendable or flexible electronic device. The display device may be a non-self-luminous display device or a self-luminous display device. The antenna device may be a liquid crystal type antenna device or a non-liquid crystal type antenna device, and the sensing device may be a sensing device that senses capacitance, light, heat energy or ultrasonic waves, but is not limited thereto. The electronic device may include passive elements and active elements, such as capacitors, resistors, inductors, diodes, transistors, etc. Diodes may include light-emitting diodes or photoelectric diodes. The light-emitting diodes may include, for example, organic light-emitting diodes (OLEDs), submillimeter light-emitting diodes (mini LEDs), micro light-emitting diodes (micro LEDs) or quantum dot light-emitting diodes (quantum dot LEDs), but not limited to this. The splicing device may be, for example, a display splicing device or an antenna splicing device, but is not limited thereto. It should be noted that the electronic device may be any combination of the above, but is not limited thereto. In the following, a display device will be used as an electronic device or a splicing device to illustrate the disclosure, but the disclosure is not limited thereto.

The antenna device may be, for example, a 5G antenna, a Beyond-5G antenna, a 6G antenna, a liquid crystal antenna, a phased array antenna, a low-orbit satellite antenna, or other types of antennas, but is not limited thereto. The antenna device may, for example, include a spliced antenna device, but is not limited thereto. It should be noted that the electronic device may be any combination of the above, but is not limited thereto. In addition, the shape of the electronic device may be a rectangular shape, a circular shape, a polygonal shape, a shape with curved edges, or other suitable shapes. Electronic devices may have peripheral systems such as drive systems, control systems, light source systems, and shelf systems to support the display device, the antenna device, or the splicing device. The electronic device of the present disclosure may be, for example, a display device, but is not limited thereto.

The present disclosure provides an electronic device, in which a groundable circuit board at least includes a first ground terminal and a second ground terminal, and is electrically connected to a conductive housing (which will be referred to as housing in the following content) through the first ground terminal and the second ground terminal. In addition, according to the electrical measurement method of the present disclosure, when testing the impedance of the electronic device, a test board provides a constant current to one of the ground terminals of the circuit board and outputs a voltage value, and the other ground terminal is still grounded, thereby forming a connected path. As a result, an impedance value can be measured through the constant current and the voltage value. The circuit board may be at least part of the module circuit board, and the wiring in the circuit board may be designed according to the design requirements of the electronic device. By configuring the first ground terminal and the second ground terminal in the circuit board, the test board and a jig can be directly used to evaluate whether there is good electrical contact between the housing and the circuit board of the electronic device without the need for other additional facilities, such as the aforementioned test platform. Since the housing is electrically connected to the test board through conductive media during the electrical measurement, the electronic device disclosed in the present disclosure can omit additional facilities required for measuring impedance to reduce manufacturing costs, and reduce the problem of incomplete electrical contact caused by these additional facilities when measuring impedance.

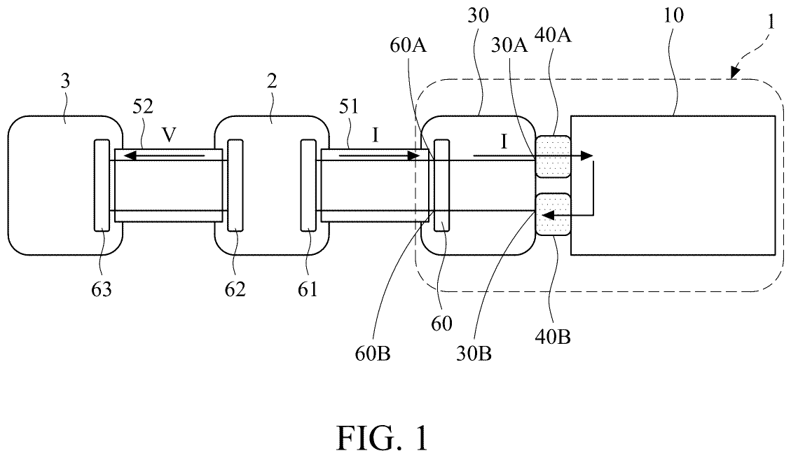

FIG. 1 illustrates a schematic diagram of an electrical measurement method of an electronic device 1, in accordance with some embodiments of the present disclosure. The electrical measurement method may include disposing a housing and a circuit board, such as the housing 10 and the circuit board 30 of the electronic device 1 shown in FIG. 1. The circuit board 30 may have a first ground terminal 30A and a second ground terminal 30B. The first ground terminal 30A may be electrically connected to the housing 10 through a first conductive medium 40A, and the second ground terminal 30B may be electrically connected to the housing 10 through a second conductive medium 40B. The test board 2 may be used to provide a constant current I to the first ground terminal 30A and output a voltage value V. Then, an impedance value may be measured through the voltage value V. It should be noted that the first ground terminal 30A and the second ground terminal 30B have no electrical connection path in the circuit board 30. As a result, it will not cause a short circuit during the electrical measurement and cause the measurement failure.

The electrical measurement method may further include disposing a connector 60 including a first contact 60A on the circuit board 30. In some embodiments, the first contact 60A is electrically connected to the first ground terminal 30A and the test board 2, and the test board 2 provides the constant current I to the first ground terminal 30A through the first contact 60A. The connector 60 may further include a second contact 60B, and the second contact 60B is electrically connected to the second ground terminal 30B and the test board 2.

The impedance value may be measured by a jig 3 electrically connected to the test board 2. The connector 60 of the electronic device 1 may be electrically connected to a connector 61 of the test board 2 through a cable 51, and a connector 62 of the test board 2 may be electrically connected to a connector 63 of the jig 3 through a cable 52. The cables 51 and 52 may be, for example, flexible printed circuits (FPC), but are not limited thereto. The cables 51 and 52 may include power traces and signal traces, but are not limited thereto. The constant current I provided by the test board 2 may flow to the electronic device 1 via the cable 51 and then return to the test board 2 via the cable 51 to form a loop. Thereby, the test board 2 may measure the voltage value V and output the voltage value V to the jig 3 via the cable 52. Furthermore, the jig 3 may include a device capable of measuring impedance values based on analog voltage values.

In some embodiments, the constant current I provided by the test board 2 sequentially passes through the connector 60, the first ground terminal 30A, the first conductive medium 40A, the housing 10, the second conductive medium 40B, and the second ground terminal 30B in the electronic device 1, and then flow back to the test board 2 via the connector 60, but the present disclosure is not limited thereto. Therefore, the impedance value measured by the jig 3 can be used to evaluate the equivalent impedance of the electronic device 1. The ideal impedance value of the equivalent electrical loop formed by the electrical connection of the above components should be less than or equal to 10 ohms (Ω), and when the conductive media 40A and 40B are normally attached to the ground terminals 30A and 30B and the housing 10, the impedance value of the housing 10 itself should account for most of the impedance of the equivalent electrical loop, and the impedances of the conductive media 40A and 40B and other components may be ignored. If the impedance value converted from the voltage value V by the jig 3 is too high, it can be inferred that the first conductive medium 40A and the second conductive medium 40B have an adhesion abnormality problem.

The wiring in the circuit board 30 of the present disclosure may be designed according to the design requirements of the electronic device 1. By disposing the first ground terminal 30A and the second ground terminal 30B in the circuit board 30, the test board 2 and the jig 3 can be directly used to evaluate whether there is good electrical contact between the housing 10 and the circuit board 30 of the electronic device 1. Such an electrical measurement method can reduce the testing costs and reduce the problem of incomplete electrical contact. In addition, it should be noted that after the test is completed, the first ground terminal 30A and the second ground terminal 30B still maintain contact with the housing, so that the electronic device 1 can reduce phenomena such as electromagnetic interference (EMI) and/or electrostatic discharge (ESD) through grounding when in use. Here, the first contact 60A and the second contact 60B of the connector 60 may not be electrically connected to any signal source.

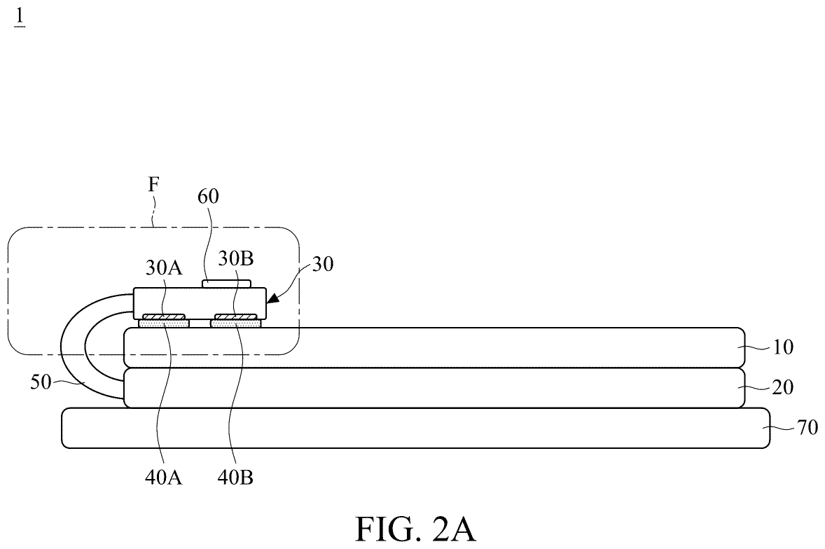

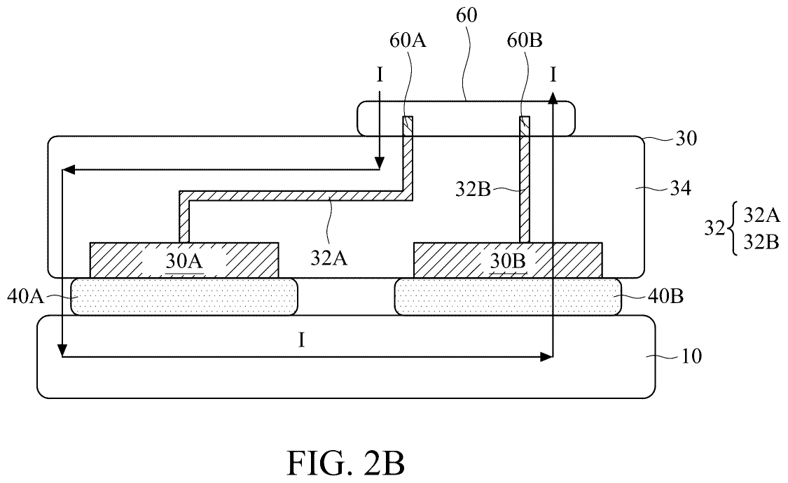

The detailed configuration of the electronic device 1 will be described below through FIGS. 2A and 2B.

FIG. 2A illustrates a cross-sectional view of the electronic device 1, in accordance with some embodiments of the present disclosure. The electronic device 1 may include the housing 10, a panel 20 disposed on the housing 10, and the circuit board 30 electrically connected to the panel 20. The circuit board 30 may have the first ground terminal 30A and the second ground terminal 30B. The first ground terminal 30A may be electrically connected to the housing 10 through the first conductive medium 40A, and the second ground terminal 30B may be electrically connected to the housing 10 through the second conductive medium 40B.

The housing 10, for example, may be a conductive housing as the outermost layer of a backlight module of the electronic device 1. The material of the housing 10 may include, for example, aluminum, stainless steel, other suitable materials, or a combination thereof, but is not limited thereto. In some embodiments, the first conductive medium 40A and second conductive medium 40B are separated from each other. The first conductive medium 40A and the second conductive medium 40B may be sandwiched between the circuit board 30 and the housing 10. The materials of the first conductive medium 40A and the second conductive medium 40B may include, for example, conductive glue, solder, silver paste, metal foil (such as silver foil, copper foil, aluminum foil, tin foil), conductive composite materials, other suitable materials or combinations thereof, but not limited to these.

The panel 20 may be any suitable type of display panel, such as a liquid crystal display panel, a light-emitting diode display panel such as an organic light-emitting diode (OLED), a sub-millimeter light-emitting diode (mini LED), a micro LED or a quantum dot LED display panel, but the present disclosure is not limited thereto. A covering substrate 70 may be further disposed on the panel 20. By disposing the covering substrate 70 on the panel 20, moisture can be reduced from entering the interior of the panel 20. According to some embodiments, when the hardness of the covering substrate 70 is sufficiently high, damages to the panel 20 when external objects collide with the electronic device 1 can be avoided, but the present disclosure is not limited to this. The material of the covering substrate 70 may include, for example, glass, polyimide (PI), polyethylene terephthalate (PET), other suitable materials, or a combination thereof, but is not limited thereto.

In some embodiments, as shown in FIG. 2A, the electronic device 1 may further include a flexible circuit board 50. The circuit board 30 may be electrically connected to the panel 20 through the flexible circuit board 50. The flexible circuit board 50 may include, for example, a wiring substrate and a protective film, but is not limited thereto. The wiring substrate may include a wiring including copper foil and a core layer including polyimide (PI), for example. In addition, the flexible circuit board 50 may further include the protective film for surface insulation. The cables 51 and 52 shown in FIG. 1 may have the same or similar material as the flexible circuit board 50, but are not limited thereto. It should be noted that in FIGS. 2A and 2B, the orientations of the installation positions of the connector 60, the first ground terminal 30A, the first conductive medium 40A, the second conductive medium 40B, and the second ground terminal 30B are along the long side of the housing. Although this is different from the installation positions in FIG. 1, the installation positions of the components in FIGS. 2A and 2B are simply examples, and the present disclosure is not limited thereto.

FIG. 2B illustrates a local cross-sectional view of the electronic device 1 as shown in FIG. 2A, in accordance with some embodiments of the present disclosure. FIG. 2B corresponds to a box F in FIG. 2A. As previously mentioned, the connector 60 may include the first contact 60A and the second contact 60B. As shown in FIG. 2B, the first contact 60A may be electrically connected to the first ground terminal 30A, and the second contact point 60B may be electrically connected to the second ground terminal 30B. The first contact 60A and the second contact 60B may include any suitable conductive material.

As shown in FIG. 2B, in some embodiments, the circuit board 30 includes wirings 32 and an insulating layer 34. The wirings 32 may include a first wiring 32A and a second wiring 32B that are electrically connected to the first ground terminal 30A and the second ground terminal 30B respectively. The first contact 60A and the second contact 60B may be electrically connected to the first ground terminal 30A and the second ground terminal 30B through the first wiring 32A and the second wiring 32B respectively. The insulating layer 34 may separate the first ground terminal 30A and the first wiring 32A from the second ground terminal 30B and the second wiring 32B in the circuit board 30. It should be noted that the circuit board 30 may be a multi-layer structure. More specifically, the circuit board 30 may include multiple sub-layers (not shown). Each sub-layer may have wirings extending along the surface of the sub-layer, and electrical connections may also be formed between the sub-layers through via holes. The first wiring 32A and the second wiring 32B may be respectively composed of parts of these wirings and these via holes.

The first ground terminal 30A, the second ground terminal 30B, the first wiring 32A, and the second wiring 32B may include the same or similar conductive materials, such as aluminum, copper, silver, gold, other suitable materials or combinations thereof, but not limited to these. The insulating layer 34 may include dielectric materials, such as PrePreg, photosensitive dielectric materials (photoimageable dielectric (PID)), photosensitive polymers (such as benzocyclobutene and benzocyclobutene), ABF (Ajinomoto build-up film), fiberglass resin composite materials, solder resist paint, other suitable materials or combinations thereof, but not limited to these.

FIG. 2B shows the flow path of the current I in the electronic device 1. Specifically, the constant current I provided by the test board 2 enters the circuit board 30 via the connector 60. Then, the constant current I may sequentially pass through the first ground terminal 30A, the first conductive medium 40A, the housing 10, the second conductive medium 40B, and the second ground terminal 30B in the electronic device 1, but is not limited thereto. Then, the constant current I may return to the test board 2 via the connector 60, as shown in FIG. 1.

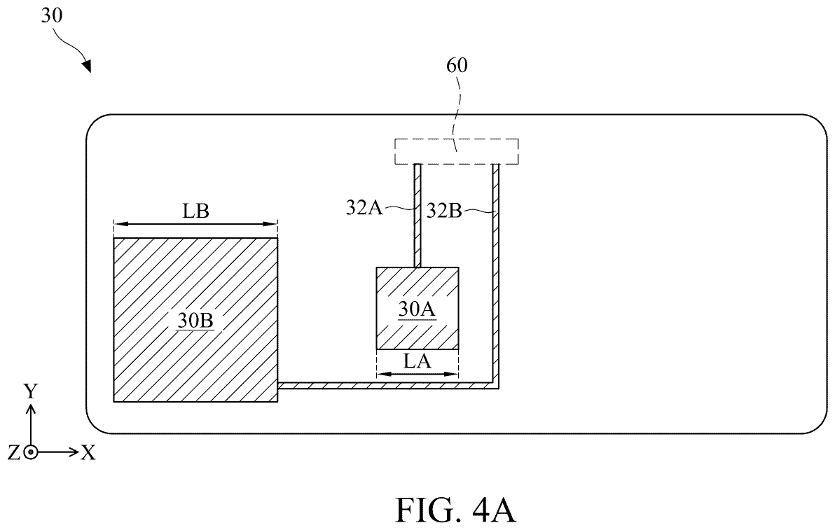

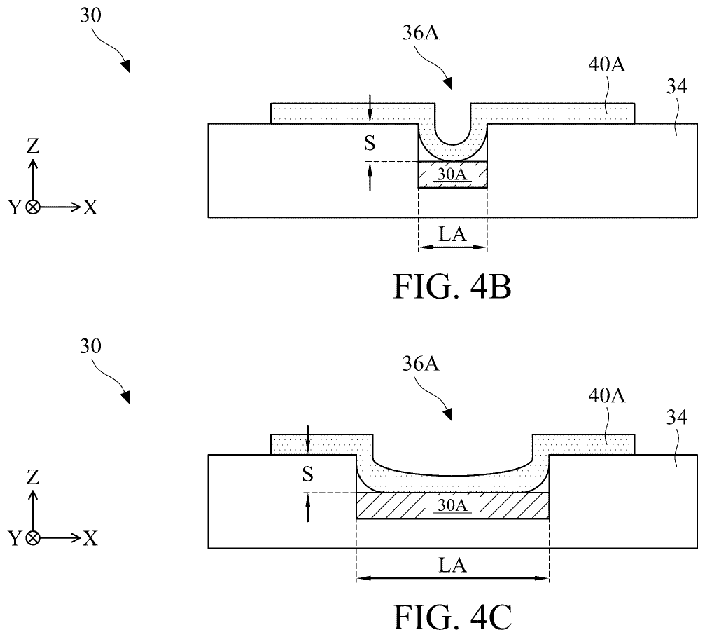

It should be understood that the structures of the first ground terminal 30A and the second ground terminal 30B are not shown in detail in FIGS. 2A and 2B. In fact, the first conductive medium 40A and the second conductive medium 40B may respectively correspond to the first ground terminal 30A and the second ground terminal 30B exposed from the insulating layer 34, and the sides adjacent to the first ground terminal 30A and the second ground terminal 30B have non-flat surfaces. For example, as shown in FIG. 4C, the first conductive medium 40A may be disposed directly above the first ground terminal 30A exposed from the insulating layer 34, and the side adjacent to the first ground terminal 30A has a non-flat surface. In addition, referring to FIG. 4C, top surfaces of the first and second ground terminals 30A and 30B may be lower than a top surface of the insulating layer 34. The present disclosure does not particularly limit the cross-sectional shapes of the first ground terminal 30A and the second ground terminal 30B.

It should be understood that the areas of the first ground terminal 30A and the second ground terminal 30B exposed from the insulating layer 34 are not the entire areas of the individual conductive layers. That is, the first ground terminal 30A and the second ground terminal 30B may be ground surfaces of respective conductive layers partially exposed from the insulating layer 34. For example, the ratio of the area of the first ground terminal 30A to the area of the conductive layer to which it belongs may be between about 0.04 and 1 (0.04≤ the area of the first ground terminal/the area of the conductive layer to which it belongs ≤1), and the ratio of the area of the second ground terminal 30B to the area of the conductive layer to which it belongs may be between about 0.04 and 1 (0.04≤the area of the second ground terminal/the area of the conductive layer to which it belongs ≤1).

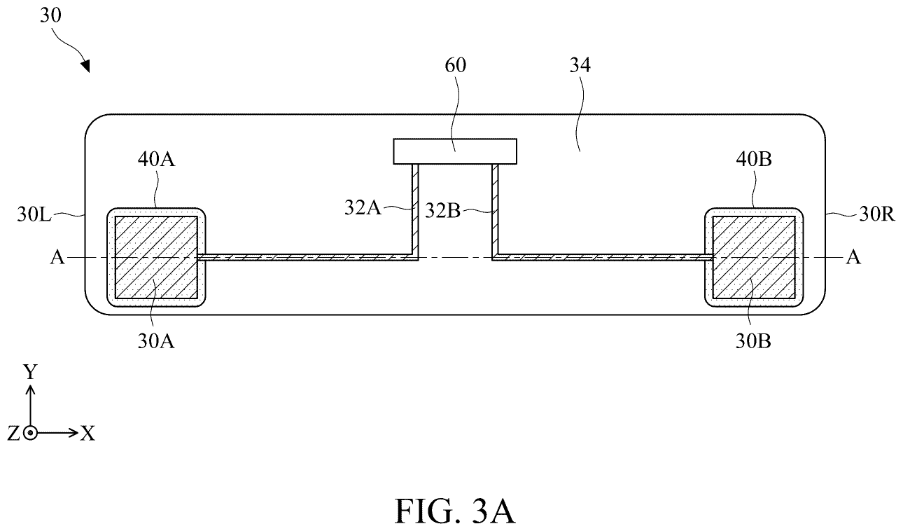

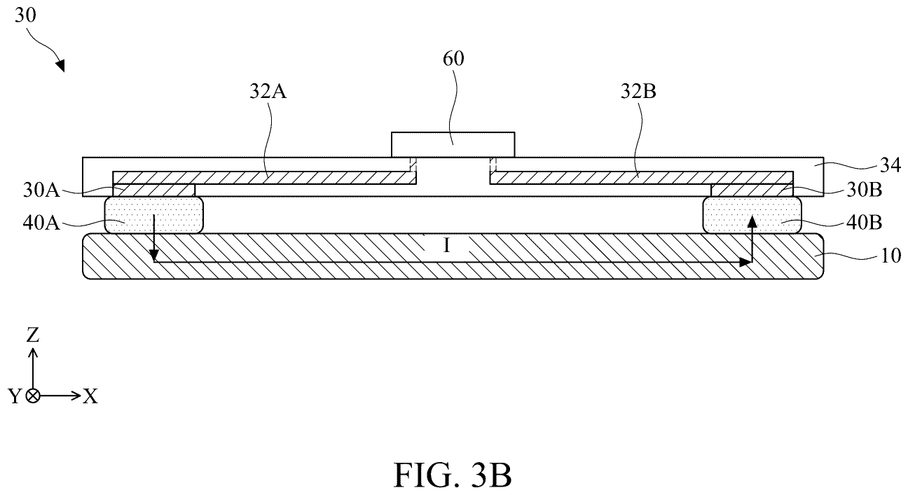

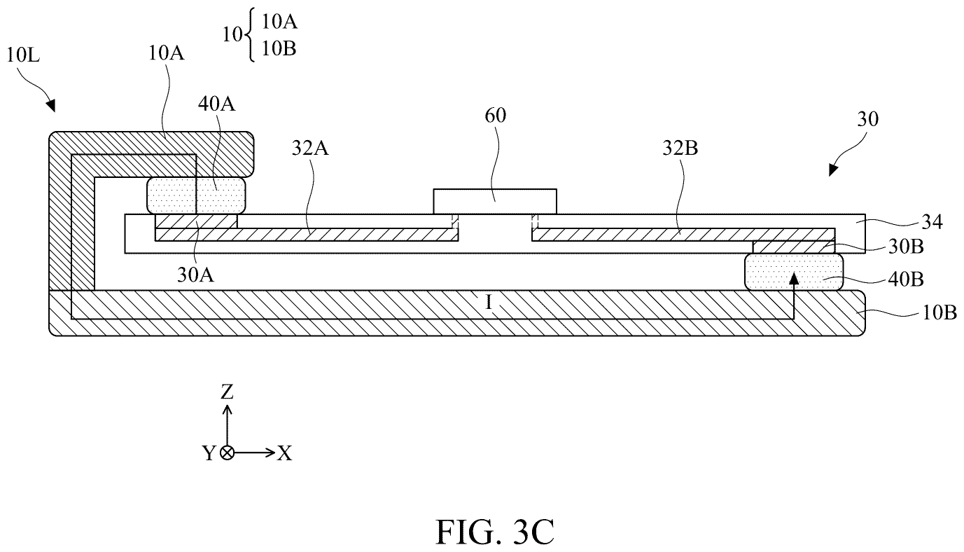

FIG. 3A illustrates a schematic top view depicting a routing design of the circuit board 30, in accordance with some embodiments of the present disclosure. Referring to FIG. 3A, the circuit board 30 may have a first side 30L and a second side 30R that are opposite to each other in a top view, and the first ground terminal 30A is close to the first side 30L, and the second ground terminal 30B is close to the second side 30R, but the present disclosure is not limited thereto.

FIG. 3B illustrates a side view of the electronic device 1 viewed from a section line A-A in FIG. 3A and along the Y direction, in accordance with some embodiments of the present disclosure. In some embodiments, the first ground terminal 30A and the second ground terminal 30B are located on the same surface of the circuit board 30, such as the lower surface of the circuit board 30 in FIG. 3B. It should be understood that for simplicity, the contacts in connector 60 are not shown in the following figures.

FIG. 3C illustrates a side view of the electronic device 1 corresponding to the section line A-A in FIG. 3A and viewed along the Y direction, in accordance with some other embodiments of the present disclosure. In some embodiments, the first ground terminal 30A and the second ground terminal 30B are located on opposite surfaces of the circuit board 30. For example, referring to FIG. 3C, the first ground terminal 30A may be located on the upper surface of the circuit board 30, and the second ground terminal 30B may be located on the lower surface of the circuit board 30.

In some embodiments, the housing 10 includes a first conductive part 10A and a second conductive part 10B connected to each other, and the first conductive part 10A and the second conductive part 10B are respectively connected to the first conductive medium 40A and the second conductive medium 40B. At least one of the first conductive part 10A and the second conductive part 10B may have a bent part 10L, so that the housing 10 overlaps with the opposite sides of the circuit board 30 at the same time, as shown in FIG. 3C. Referring to FIG. 3C, the first wiring 32A, the first ground terminal 30A, the first conductive medium 40A, the first conductive part 10A, the second conductive part 10B, the second conductive medium 40B, the second ground terminal 30A, and the second wiring 32B can jointly form a conductive path to allow the current I to pass.

FIG. 4A illustrates a schematic top view depicting a routing design of the circuit board 30, in accordance with some embodiments of the present disclosure. In FIG. 4A, in order to clearly illustrate the size relationship between the first ground terminal 30A and the second ground terminal 30B, the first conductive medium 40A and the second conductive medium 40B are omitted. The ratio of the area of the first ground terminal 30A to the area of the second ground terminal 30B may be between 0.04 and 1 (0.04≤first ground terminal area/second ground terminal area≤1). In some embodiments, as shown in FIG. 4A, the first ground terminal 30A has a first characteristic length LA, the second ground terminal 30B has a second characteristic length LB, and the first characteristic length LA is between 3 millimeters (mm) and the second characteristic length LB (3 mm≤LA≤LB). As a result, good adhesion can be achieved between the first conductive medium 40A and the first ground terminal 30A. If the first characteristic length LA is less than 3 mm, the adhesion between the first conductive medium 40A and the first ground terminal 30A will be affected, and the equivalent impedance within the electronic device 1 will become higher. The following will describe the influence of the first characteristic length LA on the adhesion between the first conductive medium 40A and the first ground terminal 30A with reference to FIGS. 4B and 4C.

FIG. 4B illustrates a local cross-sectional view of the circuit board 30 including the first ground terminal 30A having a smaller first characteristic length LA, in accordance with some embodiments of the present disclosure. FIG. 4C illustrates a local cross-sectional view of the circuit board 30 including the first ground terminal 30A having a larger first characteristic length LA, in accordance with some embodiments of the present disclosure. As shown in FIGS. 4B and 4C, the first ground terminal 30A may be exposed in a first ground opening 36A in the insulating layer 34 of the circuit board 30. There is a step difference S between the top surface of the first ground terminal 30A and the top surface of the insulating layer 34. The step difference S may be between about 10 and 50 micrometers (μm) (10 μm≤ step difference≤50 μm). As shown in FIG. 4B, if the first characteristic length LA is too small, the contact area between the first conductive medium 40A and the first ground terminal 30A will become insufficient, causing the first conductive medium 40A and the first ground terminal 30A unable to laminate tightly due to the step difference S. In contrast, as shown in FIG. 4C, if the first characteristic length LA is larger, there will be a larger and flat contact surface between the first conductive medium 40A and the first ground terminal 30A. As a result, the first conductive medium 40A and the first ground terminal 30A will have good electrical contact. In a top view (for example, a top view in the same direction as in FIG. 4A), the contact area of the first conductive medium 40A and the first ground terminal 30A may be larger than half of the area of the first ground opening 36A.

In the embodiment shown in FIG. 4A, the first ground terminal 30A and the second ground terminal 30B are rectangular, and the first characteristic length LA and the second characteristic length LB are the side lengths of each rectangle. However, it should be understood that the present disclosure does not limit the shapes of the first ground terminal 30A and the second ground terminal 30B. The first ground terminal 30A and the second ground terminal 30B may also have other shapes, such as circles, ovals, triangles, other suitable shapes, or combinations thereof, but are not limited thereto. For example, in a specific embodiment, the first ground terminal 30A and the second ground terminal 30B are circular, and the first characteristic length LA and the second characteristic length LB are diameters of the circles.

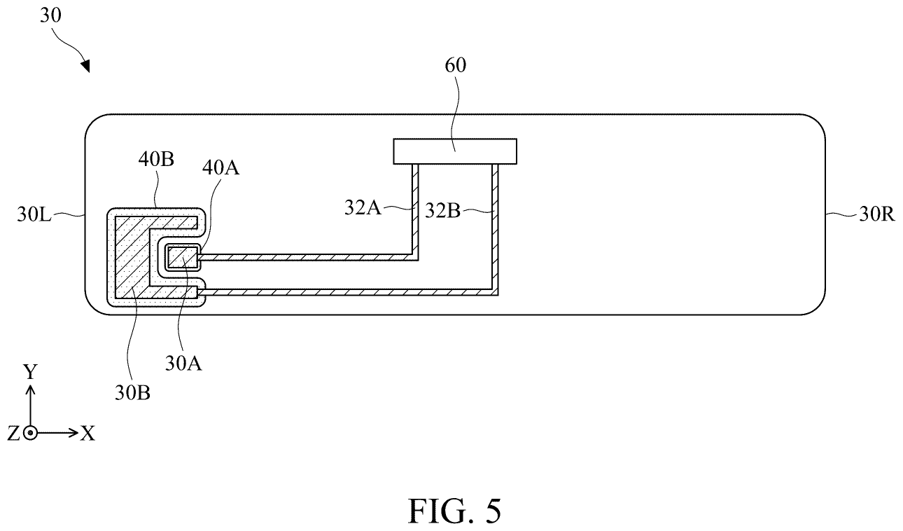

FIG. 5 illustrates a schematic top view depicting a routing design of the circuit board 30, in accordance with some embodiments of the present disclosure. The first ground terminal 30A and the second ground terminal 30B may be close to the same side of the circuit board 30. In some embodiments, as shown in FIG. 5, both the first ground terminal 30A and the second ground terminal 30B are close to the first side 30L of the circuit board 30. As shown in FIG. 5, the first ground terminal 30A and the second ground terminal 30B may be disposed adjacent to each other. The first conductive medium 40A and the second conductive medium 40B are separated from each other, and may be configured in shapes corresponding to the first ground terminal 30A and the second ground terminal 30B respectively in FIG. 5. Furthermore, in such an embodiment, the first ground terminal 30A and the second ground terminal 30B may be located on the same surface or on opposite surfaces of the circuit board 30, which is not limited in this disclosure.

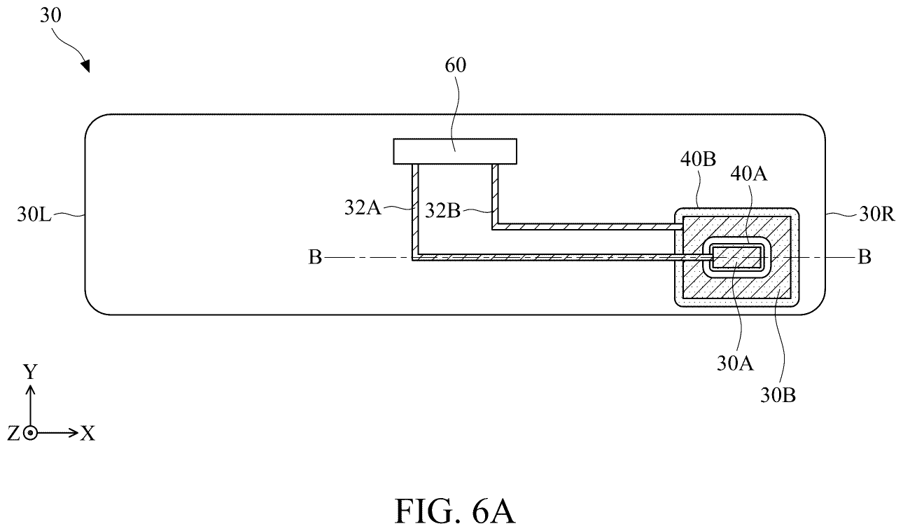

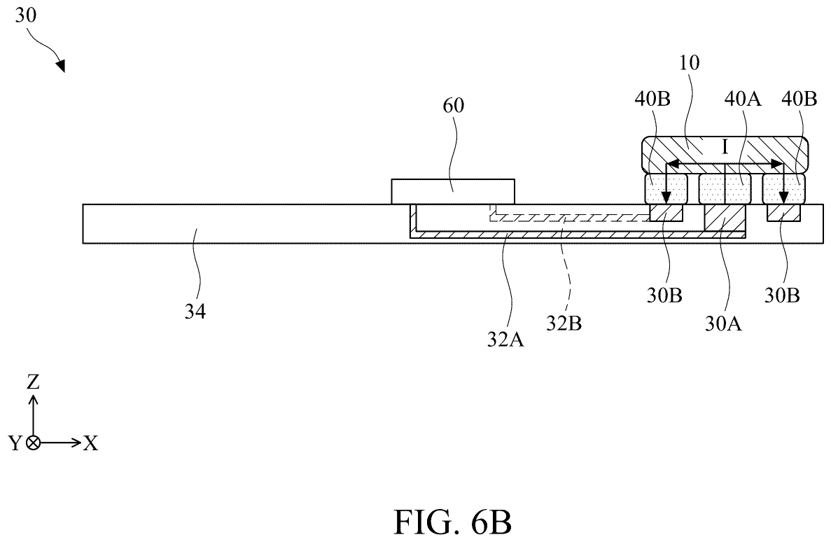

FIG. 6A illustrates a schematic top view depicting a routing design of the circuit board 30, in accordance with some embodiments of the present disclosure. The first ground terminal 30A and the second ground terminal 30B may be close to the same side of the circuit board 30. As shown in FIG. 6A, both the first ground terminal 30A and the second ground terminal 30B may be close to the second side 30R of the circuit board 30. As shown in FIG. 6A, the first ground terminal 30A and the second ground terminal 30B may be disposed adjacent to each other. The first conductive medium 40A and the second conductive medium 40B are separated from each other, and may be configured in shapes corresponding to the first ground terminal 30A and the second ground terminal 30B respectively in FIG. 6A. In some embodiments, the second ground terminal 30B surrounds the first ground terminal 30A in a top view (e.g., FIG. 6A).

FIG. 6B illustrates a side view of the electronic device 1 corresponding to a section line B-B in FIG. 6A and viewed along the Y direction, in accordance with some embodiments of the present disclosure. Referring to FIG. 6B, the first ground terminal 30A and the second ground terminal 30B may be located on the same surface of the circuit board 30, but are not limited thereto. Since the first ground terminal 30A is surrounded by the second ground terminal 30B, in order to separate the first wiring 32A and the second wiring 32B from each other, the first wiring 32A and the second wiring 32B may horizontally extend at different heights in the circuit board 30 (in other word, each of the first wiring 32A and the second wiring 32B has a part located on a different sub-layer in the circuit board 30), but not limited thereto. Referring to FIG. 6B, the first wiring 32A and the second wiring 32B may overlap in the normal direction (Z direction) of the circuit board 30, but are not limited thereto. When the internal space of the product is small, the area of the circuit board 30 may be small. With the configuration of the ground terminals as shown in FIG. 6B, the detection impedance loop of the electronic device 1 can be formed in a smaller area on the circuit board 30 to meet product design requirements.

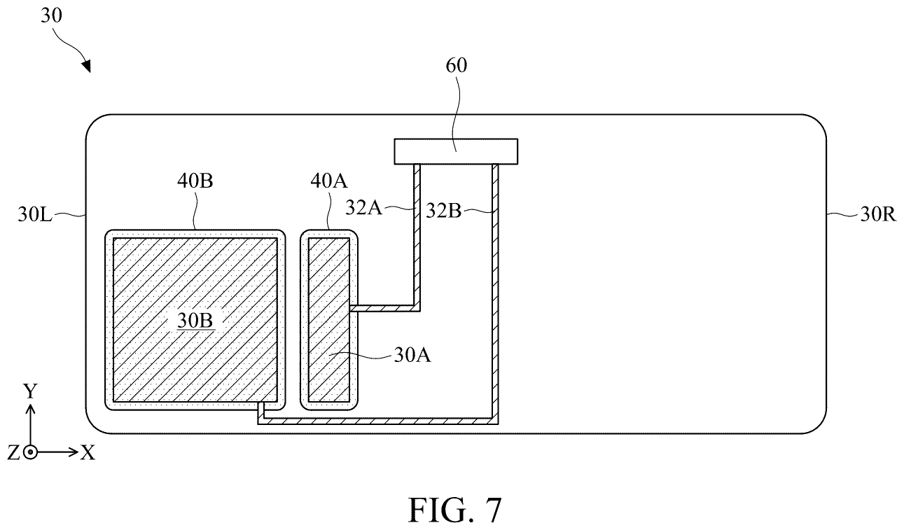

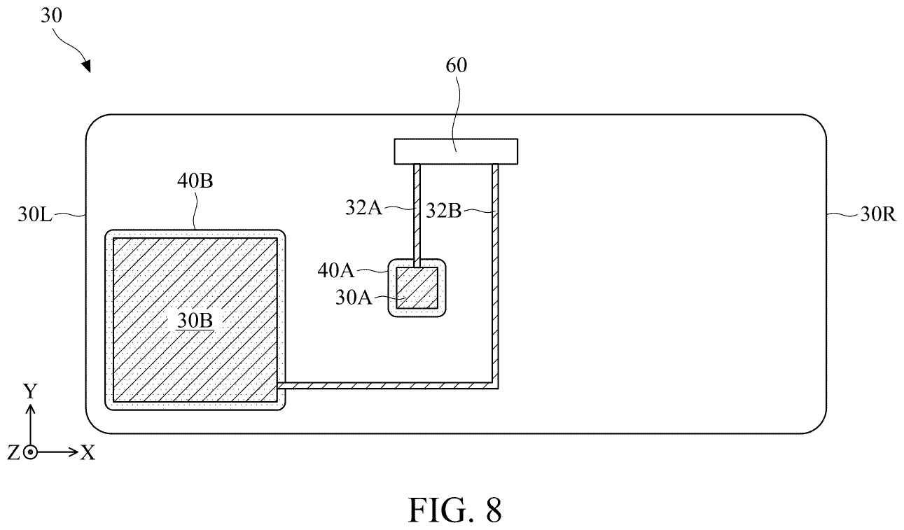

FIGS. 7 and 8 illustrate schematic top views depicting routing designs of the circuit board 30 respectively, in accordance with some embodiments of the present disclosure. As shown in FIG. 7, the first ground terminal 30A and the second ground terminal 30B may be disposed in the same area of the circuit board 30. As shown in FIG. 8, the first ground terminal 30A and the second ground terminal 30B may also be disposed in different areas of the circuit board 30.

In summary, the present disclosure provides an electronic device, in which a groundable circuit board is electrically connected to the housing through the first ground terminal and the second ground terminal. In addition, according to the electrical measurement method of the present disclosure, when testing the impedance of the electronic device, the test board provides a constant current to one of the ground terminals of the circuit board and outputs a voltage value, and the other ground terminal is still grounded, thereby forming a connected path. As a result, an impedance value can be measured through the constant current and the voltage value. The above-mentioned circuit board is at least a part of the module circuit board, and the wiring in the circuit board may be designed according to the design requirements of the electronic device. By configuring the first ground terminal and the second ground terminal in the circuit board, it is able to measure the impedance of the housing of the electronic device directly by using the test board and a jig, and/or evaluate whether there is good electrical contact between the housing and the circuit board of the electronic device.

What is claimed is:

1. An electronic device, comprising:
a housing;
a panel, disposed on the housing; and
a circuit board, electrically connected to the panel,
wherein the circuit board has a first ground terminal and a second ground terminal, and the first ground terminal and the second ground terminal have no electrical connection path within the circuit board, and the first ground terminal is electrically connected to the housing through a first conductive medium, and the second ground terminal is electrically connected to the housing through a second conductive medium.

2. The electronic device as claimed in claim 1, further comprising:
a flexible circuit board electrically connected to the panel through the flexible circuit board.

3. The electronic device as claimed in claim 1, further comprising:
a connector disposed on the circuit board and comprising a first contact and a second contact,
wherein the first contact is electrically connected to the first ground terminal, and the second contact is electrically connected to the second ground terminal.

4. The electronic device as claimed in claim 1, wherein the circuit board has a first side and a second side opposite to each other in a top view, and the first ground terminal is close to the first side, and the second ground terminal is close to the second side.

5. The electronic device as claimed in claim 1, wherein the first ground terminal and the second ground terminal are located on the same surface of the circuit board.

6. The electronic device as claimed in claim 1, wherein the first ground terminal and the second ground terminal are located on opposite surfaces of the circuit board.

7. The electronic device as claimed in claim 1, wherein the second ground terminal surrounds the first ground terminal in a top view.

8. The electronic device as claimed in claim 1, wherein an ratio of the area of the first ground terminal and the area of the second ground terminal is between 0.04 and 1.

9. The electronic device as claimed in claim 1, wherein the first ground terminal has a first characteristic length, the second ground terminal has a second characteristic length, and the first characteristic length is between 3 mm and the second characteristic length.

10. The electronic device as claimed in claim 1, wherein the circuit board comprises a first line and a second line electrically connected to the first ground terminal and the second ground terminal, respectively.

11. The electronic device as claimed in claim 10, wherein the first line and the second line extends horizontally at different heights in the circuit board.

12. The electronic device as claimed in claim 11, wherein the first line and the second line overlap in a normal direction of the circuit board.

13. The electronic device as claimed in claim 1, wherein the housing comprises a first conductive part and a second conductive part connected to each other, and the first conductive part and the second conductive part are electrically connected to the first conductive medium and the second conductive medium, respectively.

14. The electronic device as claimed in claim 1, wherein the first ground terminal is exposed in a first ground opening in an insulating layer of the circuit board.

15. The electronic device as claimed in claim 14, wherein a contact area of the first conductive medium and the first ground terminal is larger than half of an area of the first ground opening in a top view.

16. The electronic device as claimed in claim 1, wherein the first conductive medium and the second conductive medium are separated from each other.

17. An impedance measurement method, comprising:
disposing a housing;
disposing a circuit board, wherein the circuit board has a first ground terminal and a second ground terminal, and the first ground terminal and the second ground terminal have no electrical connection path within the circuit board, and the first ground terminal is electrically connected to the housing through a first conductive medium, and the second ground terminal is electrically connected to the housing through a second conductive medium;
disposing a test board to provide a constant current to the first ground terminal and output a voltage value; and
measuring an impedance value through the voltage value.

18. The impedance measurement method as claimed in claim 17, further comprising: disposing a connector comprising a first contact on the circuit board, wherein the first contact is electrically connected to the first ground terminal and the test board, and the test board provides the constant current to the first ground terminal through the first contact.

19. The impedance measurement method as claimed in claim 18, wherein the connector further comprises a second contact, and the second contact is electrically connected to the second ground terminal and the test board.

20. The impedance measurement method as claimed in claim 17, further comprising: disposing a jig, wherein the jig is electrically connected to the test board, and the jig measures the impedance value according to the voltage value.
